(19) United States
(12) Patent Application Publication
(10) Pub. No.: US 2011/0294296 A1
(43) Pub. Date: Dec. 1, 2011

(54) Using edges of self-assembled monolayers to form narrow features

(75) Inventors: Joanna Aizenberg, New Providence, NJ (US); Vikram Sundar, Hoboken, NJ (US)

(73) Assignee: Lucent Technologies Inc., Murray Hill, NJ (US)

(21) Appl. No.: 10/442,774

(22) Filed: May 21, 2003

(51) Int. Cl. H01L 21/302; H01L 21/28; H01L 21/336

(52) U.S. Cl. 438/702; 438/151; 438/666; 257/E21.409; 257/E21.214; 257/E21.158

(57) ABSTRACT

The present invention provides a method for manufacturing a structure over a semiconductor substrate. To form a trench, a patterned layer is formed on a portion of a substrate such that the patterned layer forms a target area located adjacent an edge of the patterned layer. A self-assembled monolayer (SAM) is coupled to the substrate up to the patterned layer, but excluded from the patterned layer. The substrate is then removed within the target area. A wire is formed in a similar fashion except that the first SAM is exchanged with a second SAM in the target area. Then either the substrate outside of the target area is removed, or conductive metal crystals are grown within the target area. Such structures may be advantageously used in the manufacture of a number of active or passive electronic devices, such as a field effect transistor.

### TECHNICAL FIELD OF THE INVENTION

The present invention is directed, in general, to structures and methods for manufacturing structures, and more specifically, methods to exploit disorder in a self-assembled monolayer (SAM) to produce structures.

### BACKGROUND OF THE INVENTION

There is great interest in the development of cost effective methods for the fabrication of nanostructures (structures with smallest dimensions of about 100 nanometers or less) for applications in nanoelectronics, information storage and optics. Several methods for making such structures have been proposed to replace optical lithography processes, but each have limitations. Electron beam writing, for example, is a serial process and not amenable to mass production. Both X-ray and extreme ultraviolet lithography are limited by the complexity of the procedures that use them. Microcontact printing uses an elastomeric stamp to transfer a pattern of alkanethiol molecules, which self assemble into an ordered monolayer and bind to metals, such as silver or gold, thereby serving as an etch resist for the metals. The diffusion of the alkane thiols in the printing stage, however, limits the minimum lateral dimension to about 100 nanometers. Moreover, defects are encountered on etched surfaces that are covered by the alkanethiols. Previous attempts to develop a chemical lithography process for patterning using self-assembled monolayers (SAMs) have also been problematic. For example, such methods can only be used to form a trench in a non-planar metal surface such as silver on silver structures. Such methods are also restricted to the formation of trenches in metals having a differential etch resistance to SAMs of different chain lengths.

Accordingly, an objective of the invention is a method of forming suitable structures in a broad class of metal and nonmetal surfaces that are planar when the method is completed.

### SUMMARY OF THE INVENTION

To address the above-discussed deficiencies, one embodiment of the present invention provides a method of manufacturing a trench in a substrate. The method comprises forming a patterned layer on a portion of a substrate such that the patterned layer forms a target area located adjacent an edge of the patterned layer. The method also includes chemically bonding a self-assembled monolayer (SAM) to the substrate up to the patterned layer, but excluding the patterned layer. The SAM includes a disordered region in the target area. The method further includes etching the substrate within the target area.

Another embodiment of the invention is a method of manufacturing a wire located over a substrate. The method includes forming a patterned layer on a portion of a substrate such that the patterned layer forms a target area located adjacent an edge of the patterned layer. The method further comprises chemically bonding a first SAM to the substrate up to the patterned layer but excluding the patterned layer. The SAM includes a disordered region in the target area. The method also comprises exchanging the first SAM with a second SAM within the target area.

Yet another embodiment of the present invention is a method of manufacturing a field effect transistor. The method comprises locating an insulating layer over a base substrate and depositing a substrate layer over the insulating layer. The method also includes forming a trench in the substrate, as described above, to expose the insulating layer and thereby form a source and a drain. The method further includes forming a gate dielectric in the trench, removing the patterned layer and forming a semiconductor structure over the gate dielectric and the source and drain.

### BRIEF DESCRIPTION OF THE DRAWINGS

The invention is best understood from the following detailed description, when read with the accompanying FIGUREs. Various features may not be drawn to scale and may be arbitrarily increased or reduced for clarity of discussion. Reference is now made to the following descriptions taken in conjunction with the accompanying drawings, in which:

FIGS. 1A-1H illustrate sectional views of intermediate structures formed by a method of manufacturing of a trench in a substrate;

FIGS. 2A-2F illustrate sectional views of the manufacturing of a wire located over substrate at various intermediate stages of manufacture; and

FIGS. 3A-3F illustrate sectional views of the manufacture of a field effect transistor at various intermediate stages of manufacture.

### DETAILED DESCRIPTION

The present invention recognizes the advantageous use of depositing a patterned layer on a substrate to facilitate the formation of narrow structures in or on a planar surface of the substrate. Because it is not protected by a SAM, the patterned layer is readily removable by a subsequent treatment thereby leaving the planar surface of the substrate with the structure formed therein or thereon. The formation of such structures in or on a planar surface is desirable because it simplifies subsequent processing steps to form active or passive device structures. Moreover, the formation of the SAM on the substrate up to, but not on, the patterned layer creates a narrower disordered region of SAMs at the edge interface between the substrate and patterned layer. This, in turn, advantageously allows the more precise formation of narrower structures in a broad number of substrates.

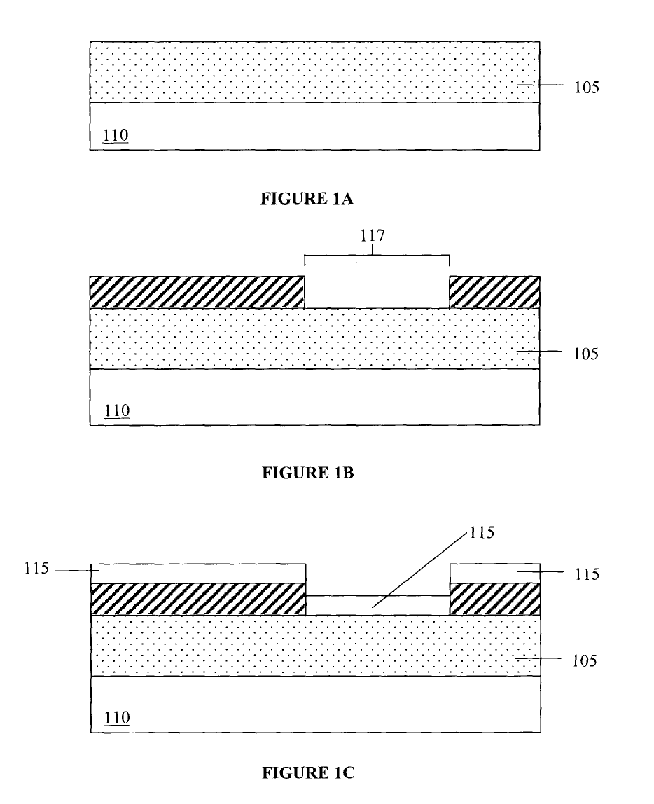

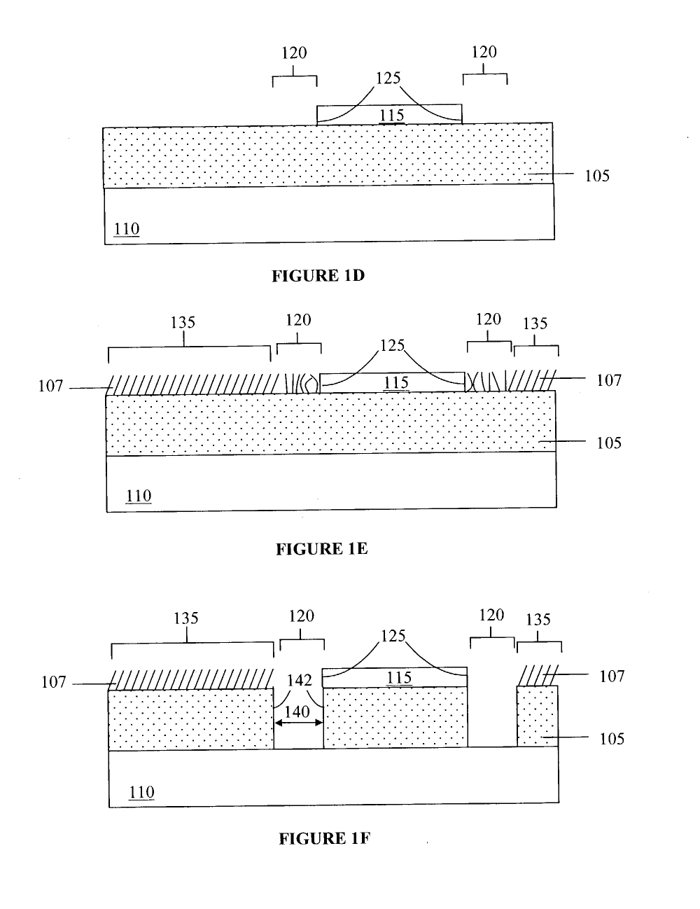

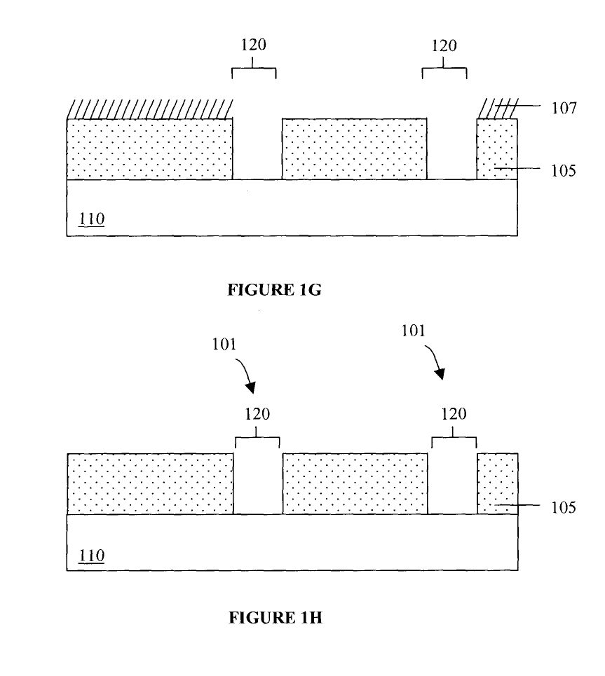

FIGS. 1A-1H illustrate sectional views of intermediate structures by one embodiment of the method for manufacturing a trench 101. The trench 101 is in a substrate 105 located over a base substrate 110. In certain embodiments, the base substrate 110 is a semiconductor substrate 110, although those skilled in the art would recognize that a number of other materials, such as gallium arsenide or germanium, could be suitable base substrates 110. The substrate 105 is formed over the base substrate 110 by conventional techniques, such as evaporation (FIG. 1A). The substrate 105 comprises a metal or non-metal capable of binding to a SAM 107 (FIG. 1E). Exemplary substrate materials 105 include gold, silver, copper, platinum, palladium, aluminum or mixtures thereof, or silicon. It is advantageous to employ the method to manufacture the trench 101 in substrates, such as palladium, that are compatible with conventional complimentary metal oxide semiconductor processing. The method is also advantageously applied to the manufacture of trenches 101 in substrates such as palladium where there is no differential etch resistance between SAMs 107 of different chain lengths.

As depicted in FIGS. 1B-1D, the method includes forming a patterned layer 115 on a portion 117 of the substrate 105. The patterned layer 115 is formed so as to form a target area 120 located adjacent an edge 125 of the patterned layer 115. The patterned layer 115 is formed by a conventional deposition of photoresist 130 on the substrate 105, which is then patterned by photolithography. In certain preferred embodiments, shown in FIG. 1C, the patterned layer 115 is deposited over the photoresist 130 and substrate 105. As illustrated in FIG. 1D, after conventional lift off of the photoresist 130, the patterned layer 115 is left on the portion 117 of the substrate 105. In alternative embodiments, the patterned layer 115 is formed on the substrate 105 by conventional evaporation of the patterned layer 115 through a stencil mask.

The patterned layer 115 is a compound that is inert to an etchant of the substrate 105 and capable of chemically bonding to the substrate 105, but not to the SAM 107. In certain embodiments, the patterned layer 115 is a metal different from the substrate 105, for example, chromium or titanium. In still other embodiments, the patterned layer 115 is an organic compound, such as a photoresist 130. Using an organic compound in the patterned layer 115 enables one to avoid the need for corrosive etchants to remove the patterned layer 115. Corrosive etchants, such as hydrogen fluoride, could damage other components. The use of photoresist 130 is particularly advantageous because conventional optical photolithography techniques may be used to form the patterned layer 115. Examples of suitable photoresist compounds, that do not chemically bind to the SAM 107, include diazo-based photoactivated photoresists containing fluoroaliphatic polymer esters. In one preferred embodiment, the patterned layer 115 comprises product number Shipley 1805 (Shipley Corporation, Marlborough, Mass.).

As illustrated in FIG. 1E, the method also includes chemically bonding a SAM 107 to the substrate 105 up to the patterned layer 115. Chemical bonding the SAM 107 to the substrate 105 includes exposing the substrate 105 to a solution or vapors containing molecules of the SAM 107. Exposure is for a sufficient period to allow the molecules to self assemble into a SAM 107 and chemically bond or adhere to the substrate 105.

The SAM 107 is excluded from the patterned layer 115. The patterned layer 115 is left uncovered by the SAM 107 because molecules of the SAM 107 do not chemically bond or adhere to the patterned layer 115. Of course, it should be understood that trace amounts of SAM 107 may weakly associate with the patterned layer 115 via weak noncovalent forces, such as electrostatic forces. Such trace amounts of SAM 107 molecule on the patterned layer 115, however, are insufficient to prevent the removal of the patterned layer by etchants, as discussed below. Therefore the uncovered patterned layer 115 can be removed by an etchant, as discussed below.

As shown in FIG. 1F, the method also includes etching to remove the substrate 105 within the target area 120. The target area 120 is located below portions of the SAM 107 that are disordered because of their proximity to the edge 125. The etchant for the substrate 105 more readily diffuses through the disordered regions of the SAM, and thereby selectively removes portions of the substrate 105 in the target area 120. Suitable substrate etchants include aqueous solutions containing ferrocyanide, ferricyanide, thiosulphate, and hydroxide, and aqueous solutions of acids such as phosphoric, nitric, acetic and sulfuric acid, or combinations thereof, as exemplified below.

The width 140 of the trench 101 can be increased or decreased depending on the duration of exposure to the substrate etchant. As an example, consider one preferred embodiment where the substrate 105 is gold, the patterned layer 115 is titanium and the SAM 107 is formed by exposing the substrate 105 to a 0.01 M solution of n-hexadecane thiol in ethanol for at least about 2 hours. The substrate 105 is exposed for different periods to an etchant comprising an aqueous solution of 10 mM potassium ferrocyanide, 1 mM potassium ferricyanide, 100 mM sodium thiosulphate and 1 M sodium hydroxide. Etching produces a trench having an about 50 nanometer width 140 after about 6 to about 12 minutes of exposure, about 70 nanometer width 140 after about 16 minutes of exposure, and about 240 to about 250 nanometers width 140 after about 60 minutes of exposure.

One skilled in the art would understand that the edges of trench 142 (FIG. 1F) formed by this method can be used to create another target area for the formation of a second trench. By repeated applications of this methodology with varying periods of etching one can create a variety of complex trench structures in substrates, such as dual damascene structures. Such structure, in turn, facilitate the fabrication of active and passive device components in an integrated circuit.

As illustrated in FIG. 1G, the method further includes removing the patterned layer 115 after etching the trench 101 into the substrate 105. One skilled in the art would understand that the composition of the etchant of the patterned layer 115 depends on the composition of the patterned layer 115. For example, when the patterned layer 115 is titanium, then the etchant preferably includes hydrogen fluoride, for example, a 1 percent aqueous solution of hydrogen fluoride. Alternatively, when the patterned layer 115 is a photoresist 130, then the etchant is acetone or a similar organic solvent.

As illustrated in FIG. 1H, the method also includes removing the SAM 107 after etching the trench 101 into the substrate 105. Again, as well understood by one skilled in the art, the composition of the SAM etchant depends on the composition of the SAM 107. When the SAM 107 comprises an alkane thiol, the etchant comprises a reactive ion etchant (RIE) with oxygen plasma as the active etchant. In certain preferred embodiments, the RIE includes about 40 mTorr oxygen, and a RF power of about 80 Watts for about 10 seconds.

The SAM 107 comprises organic molecules with a functional groups that chemically bond the organic molecules to the substrate 105. In embodiments where the substrate 105 is a metal, the organic molecules are preferably a non-branched alkane chains, and the functional groups are a thiols. Examples include organic molecules having the chemical formula: HS—(CH₂)ₙ—X, where n is between 2 and 20, and X is —CH₃ or —CO₂H. Where the substrate 105 is a layer of Al₂O₃ on Al, the organic molecules are preferably a non-branched alkane chains and the functional groups are phosphonic groups. Examples include organic molecules having the chemical formula: PO(OH)₂—(CH₂)ₙ—CH₃, where n is between 2 and 20. Where the substrate 105 is a layer of SiO₂ on Si, organic molecules are preferably non-branched alkane chains and the functional groups are silanes. Examples include organic molecules having the chemical formula: Si(Cl)₃—(CH₂)ₙ—CH₃, where n is between 2 and 20.

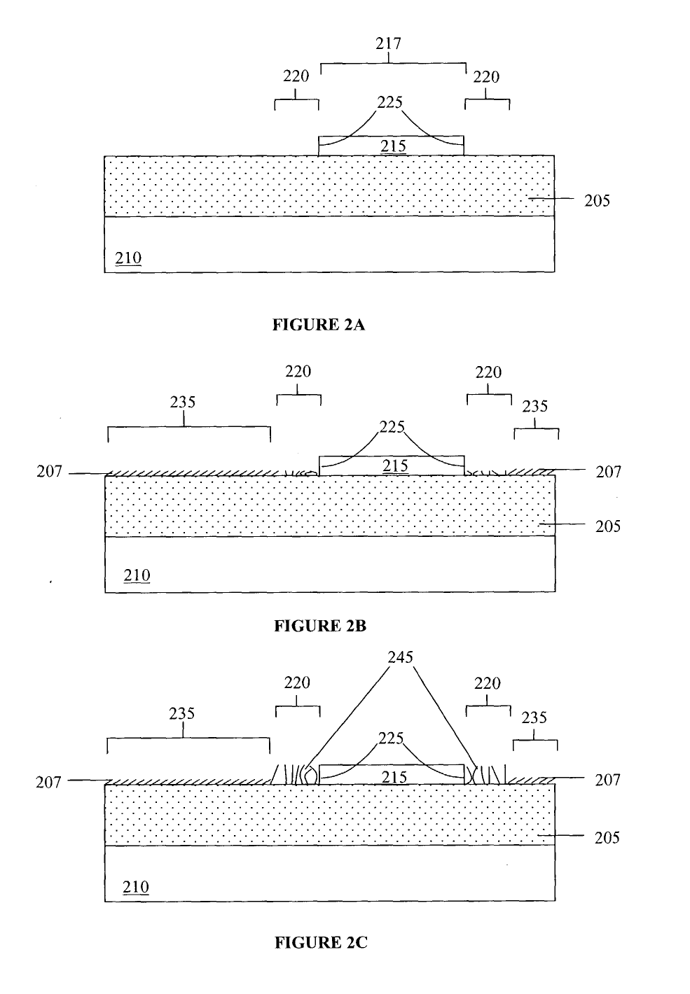

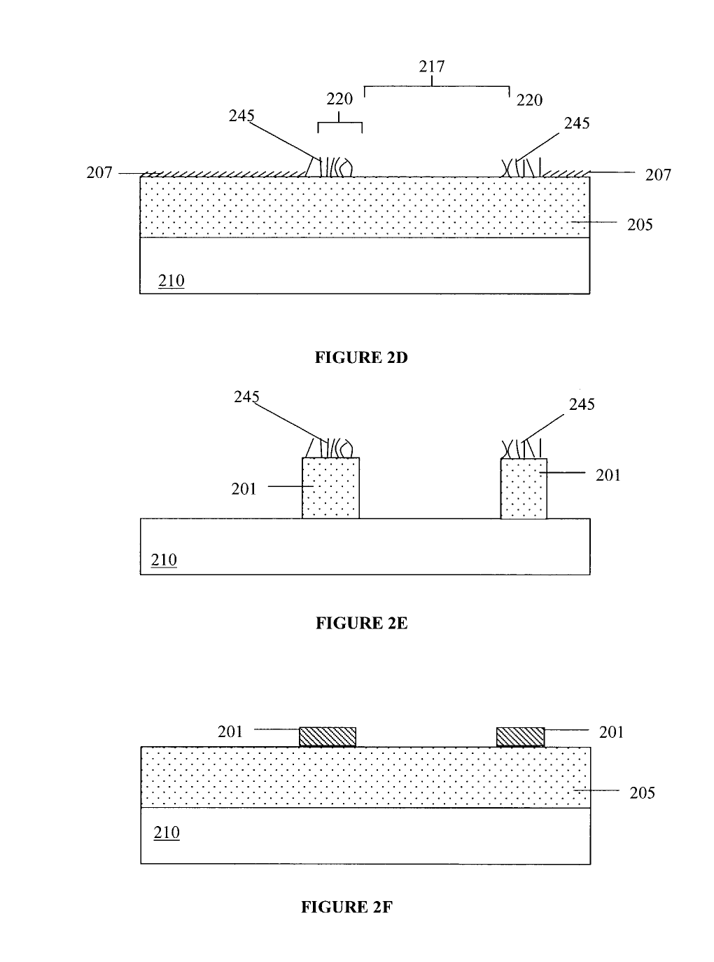

FIGS. 2A-2H illustrate structures of an embodiment of the method of manufacturing a wire 201 on a base substrate 210. Similar reference numbers are used to depict analogous structures presented in FIGS. 1A to 1H. Any of the procedures and embodiments described above may be applied to the methodology depicted in FIGS. 2A to 2H.

FIG. 2A illustrates forming a patterned layer 215 on a portion 217 of a substrate 205 such that the patterned layer 215 forms a target area 220 located adjacent an edge 225 of the patterned layer 215. The substrate 205 is formed on a base substrate 210, and the patterned layer 215 is formed thereon, using the same process as described above and illustrated in FIGS. 1A to 1D. FIG. 2B depicts chemically bonding a first SAM 207 to the substrate 205 up to the patterned layer 215, but not on the patterned layer 215, using processes analogous to that described above and illustrated in FIG. 1E.

FIG. 2C illustrates exchanging the first SAM 207 with a second SAM 245 in the target area 220. The first SAM 207 is more disordered in the vicinity of the edge 225 than in planar regions 235. Therefore, it is possible to selectively exchange the first SAM 207 for the second SAM 245 in the target area 220. Where the substrate is 205 is a metal layer, the first SAM 207 is a short chain alkane thiol having a chemical formula: HS—(CH₂)ₙ—X, where n is between 2 and 10, and X is —CH₃ or —CO₂H. In such embodiments, the second SAM 245 is a long chain alkane thiol having a chemical formula: HS—(CH₂)ₙ—X, where n is between 11 and 20, and X is —CH₃ or —CO₂H. As an example, in one preferred embodiment, the first SAM 207 is coupled to a substrate 205 of gold by exposing the substrate 205 to a solution of 10 mM HS—(CH₂)₂—CO₂H in ethanol for hours at room temperature. Then the first SAM 207 is selectively exchanged with a second SAM 245 in the target area 220 by exposing the first SAM 207 to a solution containing 10 mM of HS—(CH₂)₁₅—CO₂H in ethanol for one hour at room temperature.

FIGS. 2D and 2E illustrate a first embodiment of a method for manufacturing the wire 201. The method includes etching the substrate 205 located outside of the target area 220. As shown in FIG. 2D, etching the substrate 205 further includes exposing the patterned layer 215 to a patterned layer etchant, as described above, to remove the patterned layer 215 and thereby uncovering the portion 217 of the substrate 205. FIG. 2E illustrates that etching the substrate 205 located outside of the target area 220 further includes exposing the substrate 205 to a substrate etchant. The substrate etchant more readily diffuses through the first SAM 207 than through the second SAM 245, and thus selectively removes the substrate 205 outside of the target area 220, thereby forming the wire 201. For instance, after removing the patterned layer 215 of titanium, via exposure to hydrogen fluoride as described above, the substrate 205 of gold is exposed to a substrate etchant (e.g., an aqueous solution of 10 mM potassium ferrocyanide, 1 mM potassium ferricyanide, 100 mM sodium thiosulphate and 1 M sodium hydroxide) for about 40 seconds.

FIG. 2F illustrates a second embodiment a method for manufacturing the wire 201. The method includes nucleating growth of conductive metal crystals 201 within the target area 220. In such embodiments, it is preferable for the substrate 205 to comprise a nonconductive material, such as SiO₂ on Si. In certain preferred embodiments, the organic molecules comprising the first SAM 207 have a chemical formula of: Si(Cl)₃—(CH₂)ₙ—CH₃, where n is between 2 and 20, and the second SAM 245 has a chemical formula of: Si (Cl)₃—(CH₂)ₙ—CO₂H, where n is between 2 and 20.

Nucleating growth of conductive metal crystals comprising the wire 201 can include exposing the patterned layer 215 to an etchant, as depicted in FIG. 2D in the first embodiment, to remove the patterned layer 215 and thereby to uncover the portion 217 of the substrate 205. FIG. 2F illustrates that nucleating growth of conductive metal crystals of the wire 201 within the target area 220 further includes exposing the substrate 220 to a solution containing metal salts, such as cadmium sulphide, to form the wire 201.

After performing the above-described steps of either the first or second embodiments, if necessary, the second SAM 245 can be removed by exposure to a SAM etchant, such as the RIE procedure described above.

One skilled in the art would understand that the methods of manufacturing a wire 201 may also be used to form both linear and nonlinear structures over the substrate 205 or base substrate 210. In certain embodiments, for example, the wire 201 forms a circular structure known as quantum dots. Circular structures can be advantageously used in the fabrication of logic circuits having quantum dots to facilitate the encoding of logic states by specifying the position of individual electrons on interconnected quantum dots, such as that described by Orlov O. A. et al., Science 277:926-30 (1997) or M. L. Steigerwald et al., Ann. Rev. Mat. Sci 19:471-495 (1989), incorporated by reference herein.

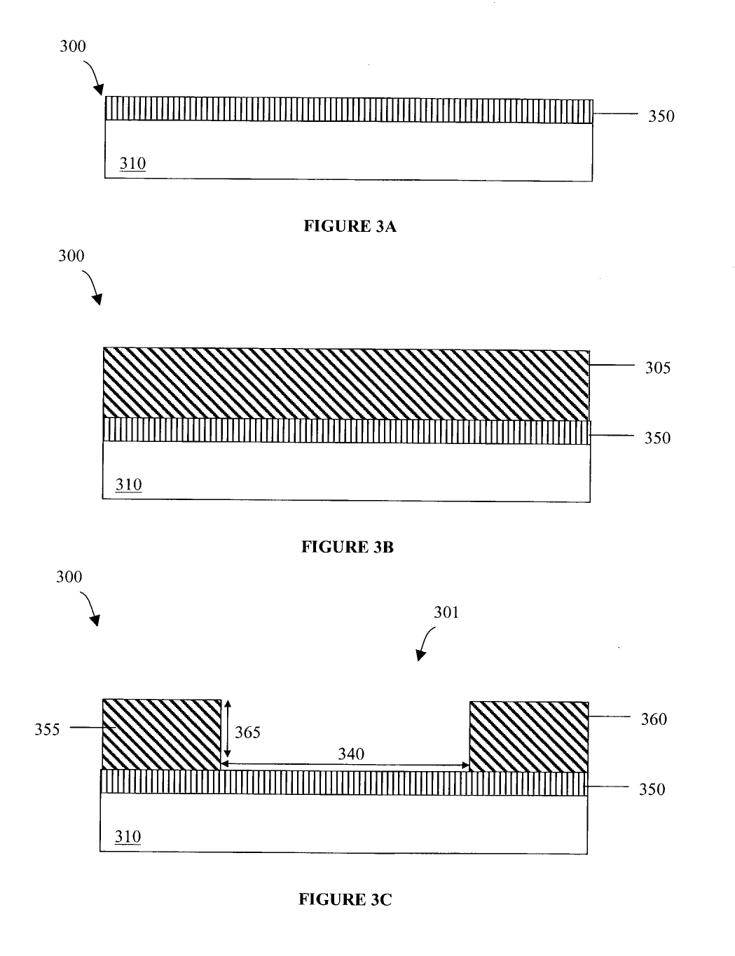

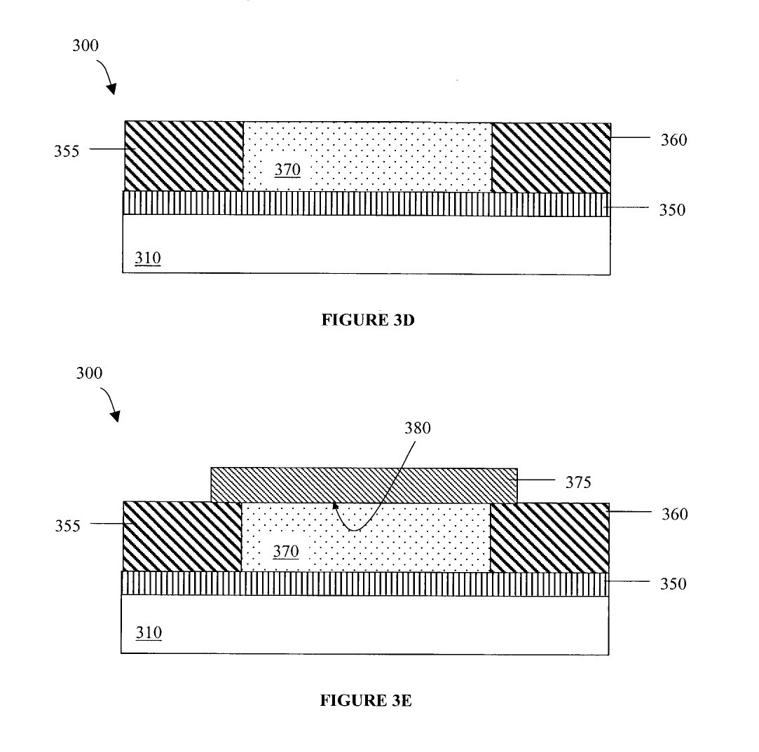

Yet another embodiment is a method of manufacturing a field effect transistor 300. The method, illustrated in FIGS. 3A to 3E, incorporates the method of forming a trench 301 (FIG. 3C) as described above. Any of the above-discussed methods of manufacturing the trench 301 may be used in the manufacture of the field effect transistor 300. One skilled in the art would understand that many alternative transistor structures in addition to the embodiment depicted in FIG. 3 could advantageously incorporate the structures of the present invention.

Using like reference numbers to depict structures analogous to that shown in FIGS. 1 and 2, the method for manufacturing the transistor 300 includes locating an insulating layer 350 over a semiconductor substrate 310 (FIG. 3A). In certain preferred embodiments, the base substrate 310 comprises a semiconductor substrates, such as polysilicon, and the insulating layer 350 comprises silicon dioxide. In such embodiments, a portion of the base substrate 310 serves as a gate for the transistor 300.

As shown in FIG. 3B, a substrate 305 of conductive material such as gold is deposited over the insulating layer 350. FIG. 3C illustrates forming a trench 301 in a substrate 305 to expose the insulating layer 350 and thereby form a separate source and drain electrodes 355, 360 from the substrate 305. In preferred embodiments, the trench 301 has a width 340 of less than about 100 nanometers and more preferably, a width 340 of about 50 nanometers. The narrow width of the trench 301 advantageously reduces the overall length of the channel of the transistor 300 as further discussed below. In certain preferred embodiments, the trench 301 has a depth 365 of between about 10 to 20 nanometers, and more preferably about 15 nanometers. Such a shallow trench depth 365 is preferred because this facilitates formation of a gate dielectric 370 (FIG. 3D).

As shown in FIG. 3D, the gate dielectric 370 is formed using conventional processes to fill the trench 301 with a dielectric material, such as silicon dioxide. Alternatively, in certain preferred embodiments, filling the trench 301 is facilitated by making the insulating layer 350 negatively charged, for example by treatment with a solution of sulfuric acid and hydrogen peroxide, followed by treatment in ammonium hydroxide and hydrogen peroxide. In preferred embodiments, the substrate 305 is then dipped inside a alkyl terminated thiol solution which selectively binds to the Au electrodes 355, 360 only and prevents deposition of the polyelectrolyte on top of the Au electrodes 355, 360. This is following by performing a multilayer deposition of a gate dielectric material 370 comprising one or more charged polyelectrolyte. For example, in certain preferred embodiments, the charged polyelectrolyte is a polyallyl amine, polyacrylic acid or mixture thereof. Once situated in the trench 301 the polyelectrolytes are charge neutral thereby making the gate dielectric material neutral and therefore insulating. One skilled in the art would understand that a variety of such layer-by-layer deposition may be used. See e.g., Dielectric Properties of Polyelectrolyte Multilayers, Durstock M. F. and Rubner M. F. Langmuir, 17:7865-72, (2001),

incorporated by reference herein in it entirety.

As illustrated in FIG. 3E, a semiconductor structure 375 is then formed over the gate dielectric 370 and the source and drain 355, 360. For example, in certain embodiments the semiconductor structure 375 is deposited through a patterned mask. The semiconductor structure 375 is comprised of a material having a low electron mobility so as to nonconducting, except when a voltage is applied to the gate 310. Such materials are well known to those skilled in the art and include pentacene or tetracene. The width of the trench 301 defines the dimension of the channel 380 located at the interface between the gate dielectric 370 and semiconductor 375.

Although the present invention has been described in detail, those of ordinary skill in the art should understand that they can make various changes, substitutions and alterations herein without departing from the scope of the invention.

1. A method of manufacturing a trench in a substrate, comprising:
forming a patterned layer on a portion of a substrate such that said patterned layer forms a target area located adjacent an edge of said patterned layer;
chemically bonding a self-assembled monolayer (SAM) to said substrate up to said patterned layer, but excluding said patterned layer, said SAM including a disordered region in said target area; and
etching said substrate within said target area.

2. The method as recited in claim 1, wherein etching further includes exposing said substrate to an etchant capable of diffusing through said SAM located at said edge and thereby selectively removing a portion of said substrate within said target area.

3. The method as recited in claim 2, further including removing said patterned layer after removing said portion of said substrate from said target area.

4. The method as recited in claim 2, further including removing said SAM after removing said portion of said substrate from said target area.

5. The method as recited in claim 1, wherein said SAM comprises one or more organic molecule having a functional group capable of chemically bonding said organic molecule to said substrate.

6. The method as recited in claim 5, wherein said organic molecule is a non-branched alkane chain and said functional group is a thiol.

7-8. (canceled)

9. A method of manufacturing a wire located over a substrate, comprising:
forming a patterned layer on a portion of a substrate such that said patterned layer forms a target area located adjacent an edge of said patterned layer;
chemically bonding a first self-assembled monolayer (SAM) to said substrate up to said patterned layer but excluding said patterned layer, said SAM including a disordered region in said target area;
exchanging said first SAM with a second SAM within said target area.

10. The method as recited in claim 9, further including etching said substrate located outside said target area.

11. The method as recited in claim 10, wherein etching said substrate further includes exposing said patterned layer to a patterned layer etchant, thereby removing said patterned layer to uncover said portion of said substrate.

12. The method as recited in claim 11, wherein said removing includes exposing said substrate to a substrate etchant such that said substrate etchant is capable of diffusing through said first SAM and thereby removing said substrate in a vicinity below said first SAM.

13. The method as recited in claim 10, wherein said first SAM is a short chain alkane thiol having a chemical formula: HS—(CH₂)ₙ—X, where n is between 2 and 10, and X is —CH₃ or —CO₂H and said second SAM is a long chain alkane thiol having a chemical formula: HS—(CH₂)ₙ—X, where n is between 11 and 20, and X is —CH₃ or —CO₂H.

14. The method as recited in claim 9, further including nucleating growth of conductive metal crystals within said target area.

15. The method as recited in claim 14, wherein said first SAM is has a chemical formula: Si(Cl)₃—(CH₂)ₙ—CH₃, where n is between 2 and 20, and said second SAM has a chemical formula of Si(Cl)₃—(CH₂)ₙ—CO₂H, where n is between 2 and 20.

16. The method as recited in claim 9, wherein said wire forms a circular structure.

17. A method of manufacturing a field effect transistor, comprising:
locating an insulating layer over a base substrate;
depositing a substrate layer over said insulating layer;
forming a trench in said substrate, including:
forming a patterned layer on a portion of said substrate layer such that said patterned layer forms a target area located adjacent an edge of said patterned layer;
chemically bonding a self-assembled monolayer (SAM) to said substrate layer up to said patterned layer, but excluding said patterned layer, said SAM including a disordered region in said target area; and
etching said substrate layer within said target area to expose said insulating layer and thereby form a source and a drain;
forming a gate dielectric in said trench;
removing said patterned layer; and
forming a semiconductor structure over said gate dielectric and said source and drain.

18. The method as recited in claim 17, wherein said trench has a width of less than about 100 nanometers.

19. The method as recited in claim 17, wherein said gate dielectric comprises a polyelectrolyte.

20. The transistor as recited in claim 19, wherein said polyelectrolyte is selected from the group of polymers consisting of:
polyallyl amine;
polyacrylic acid; and
mixtures thereof.

21. A method of manufacturing a field effect transistor, comprising:
locating an insulating layer over a base substrate;
depositing a substrate layer over said insulating layer;
forming a trench in said substrate, as recited in claim 1, wherein said etching said substrate layer within said target area comprises exposing said insulating layer to thereby form a source and a drain;
forming a gate dielectric in said trench;
removing said patterned layer; and
forming a semiconductor structure over said gate dielectric and said source and drain.

22. The method as recited in claim 21, wherein said trench has a width of less than about 100 nanometers.

23. The method as recited in claim 21, wherein said gate dielectric comprises a polyelectrolyte.

24. The method as recited in claim 23, wherein said polyelectrolyte is selected from the group of polymers consisting of:
polyallyl amine;
polyacrylic acid; and
mixtures thereof.

25. The method as recited in claim 1, wherein said patterned layer comprises a metal that said SAM does not chemically bond to.

26. The method as recited in claim 1, wherein said metal comprises chromium or titanium.

27. The method as recited in claim 1, wherein said patterned layer comprises a photoresist that said SAM does not chemically bond to.

28. The method as recited in claim 1, wherein said photoresist comprises a diazo-based photoactivated photoresist.
